(19) United States
(12) Patent Application Publication
(10) Pub. No.: US 2025/0096057 A1
(43) Pub. Date: Mar. 20, 2025

(54) ELECTRONIC COMPONENT

(71) Applicant: STMicroelectronics International N.V., Geneva (CH)

(72) Inventors: Michael DE CRUZ, Monnaie (FR); Laurent BARREAU, Joue Les Tours (FR)

(73) Assignee: STMicroelectronics International N.V., Geneva (CH)

(21) Appl. No.: 18/827,353

(22) Filed: Sep. 6, 2024

(30) Foreign Application Priority Data
Sep. 15, 2023 (FR) 2309779

(51) Int. Cl. H01L 23/31; H01L 23/00; H01L 23/29

(52) U.S. Cl. CPC H01L 23/3135; H01L 23/29; H01L 24/27; H01L 24/29; H01L 24/32; H01L 2224/27849; H01L 2224/29113; H01L 2224/29611; H01L 2224/29639; H01L 2224/29655; H01L 2224/32227; H01L 2224/32238; H01L 2924/01028; H01L 2924/01047

(57) ABSTRACT

An electronic component includes an integrated circuit chip and a package surrounding the integrated circuit chip. The electronic component includes at least a first conductive region at least partially coating one side of the integrated circuit chip. The first conductive region includes an alloy predominantly comprising bismuth.

### CROSS-REFERENCE TO RELATED APPLICATION(S)

This application claims the priority benefit of French patent application number 23/09779, filed on Sep. 15, 2023, entitled “Composant électronique,” which is hereby incorporated by reference to the maximum extent allowable by law.

### BACKGROUND

### Technical Field

The present description relates generally to electronic components and their manufacturing processes, more particularly to electronic components including at least one packaged integrated circuit chip, and to manufacturing processes for such components.

### Description of the Related Art

Electronic components including at least one packaged integrated circuit chip have been proposed. In particular, there are components including a chip-scale package (CSP). These components are generally surface-mounted on a printed circuit board, using a soldering process that involves melting and then solidifying a solder paste or flux based on a lead-free alloy, such as a tin-silver-copper alloy (Sn—Ag—Cu alloy), also known by the acronym SAC. To assemble the electronic component to the printed circuit board, a temperature above the melting point of the alloy, equal to approximately 218° C. in the case of the SAC alloy, is applied to cause the soldering material to melt. The assembly is then cooled to solidify the soldering material, thus mechanically securing the component to the board.

However, existing electronic components including a CSP package have various drawbacks. In particular, known processes for manufacturing electronic components using the SAC alloy give rise to problems of unintentional overbridging, or interconnection, between adjacent integrated circuit chips during a solder material reflow step prior to a cutting step aimed at individualizing the integrated circuit chips.

Furthermore, in certain fields of application such as automotive manufacturing, it would be desirable to have components with wettable flanks to facilitate inspection steps after soldering. However, a reflow step for SAC alloy-coated flanks during assembly would lead to undesirable slumping or flowing of this alloy onto the printed circuit board.

Furthermore, in a case where the component package surrounds several integrated circuit chips, including, for example, an ASIC (Application-Specific Integrated Circuit) chip, superimposed and interconnected by solder balls, these balls are generally made of a metal alloy, e.g., a gold-tin alloy, with a melting point higher than that of the alloy used for soldering, e.g., the SAC alloy, in order to prevent reflow of the solder balls when soldering the component to the board. As the gold-tin alloy is particularly expensive, it would be desirable to find a substitute material with a lower cost.

### BRIEF SUMMARY

Embodiments of the present disclosure overcome some or all of the drawbacks of known electronic components and their manufacturing processes.

One embodiment provides an electronic component including:
an integrated circuit chip;
a package surrounding the integrated circuit chip; and
at least a first conductive region at least partially coating one side of the integrated circuit chip, the first conductive region including an alloy predominantly including bismuth.

According to one embodiment, the alloy has a bismuth content of over 80%, preferably equal to approximately 90%.

According to one embodiment, the alloy further includes at least one additive element selected from silver, nickel and tin.

According to one embodiment, the alloy has a content of the at least one additive element of less than 10%, preferably equal to approximately 5%.

According to one embodiment, the alloy has:
a bismuth content equal to approximately 90%;
a silver content equal to approximately 5%; and
a nickel content equal to approximately 5%.

According to one embodiment, the alloy has a melting point of between 270 and 290° C.

One embodiment provides an electronic device including:
a support and interconnection substrate;
at least one contact-making element located on one face of the support and interconnection substrate;
at least one electronic component such as described; and
at least one second conductive region interposed between the at least one contact making element and the at least one first conductive region of the electronic component.

According to one embodiment, the second conductive region covers a flank of the electronic component.

According to one embodiment, the second conductive region is made of an alloy of tin, silver and copper.

One embodiment provides a motor vehicle including at least one device such as described.

One embodiment provides a method of manufacturing an electronic component including an integrated circuit chip and a package surrounding the integrated circuit chip, the method including the step of at least partially coating a face of the integrated circuit chip with a first conductive region including an alloy predominantly including bismuth.

In one embodiment, an electronic device includes an integrated circuit chip, a package surrounding the integrated circuit chip, and at least a first conductive region at least partially coating one side of the integrated circuit chip, the first conductive region including an alloy of at least 50% bismuth.

In one embodiment, a method includes surrounding an integrated circuit chip with a package. Surrounding the integrated circuit chip with a package includes at least partially coating a front face of an integrated circuit chip with a first conductive region including an alloy of at least 50% bismuth and forming an encapsulation layer on sidewalls and a back face of the integrated circuit chip.

In one embodiment, a motor vehicle includes an electronic device including a substrate and a package on the substrate. The package includes an integrated circuit chip, an encapsulation layer on a first face and on sidewalls of the integrated circuit chip, and a first conductive region at least partially coating a second face of the integrated circuit chip, the first conductive region including an alloy of at least 50% bismuth.

### BRIEF DESCRIPTION OF THE SEVERAL VIEWS OF THE DRAWINGS

These and other features and advantages will be set out in detail in the following non-limiting description of particular embodiments in relation to the accompanying figures, among which:

FIG. 1A, FIG. 1B, FIG. 1C, FIG. 1D and FIG. 1E are schematic, partial cross-sectional views illustrating successive steps in a process for manufacturing an electronic component according to one embodiment; and

FIG. 2 is a partial schematic cross-sectional view of an electronic device including an electronic component according to one embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the applications and systems in which electronic components may be provided are not detailed, the described embodiments and variants being compatible with the usual applications and systems including one or more electronic components, with possible adaptations that will be within the reach of the person skilled in the art on reading the present description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferably within 5%.

In the following description, the qualifiers “insulating” and “conductive” mean electrically insulating and electrically conductive respectively, unless otherwise specified.

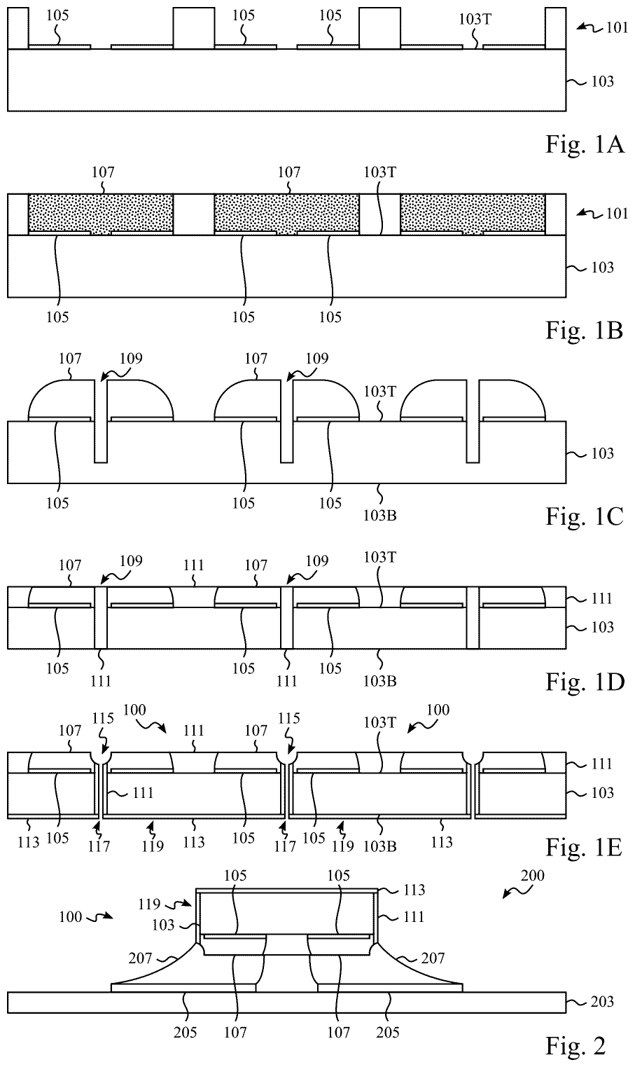

FIG. 1A, FIG. 1B, FIG. 1C, FIG. 1D and FIG. 1E are schematic, partial cross-sectional views illustrating successive steps in a process for manufacturing an electronic component 100 according to one embodiment.

FIG. 1A illustrates in particular a structure obtained at the end of a step in which a mask 101 is arranged on and in contact with a face 103T of a substrate 103 (the upper face of substrate 103, in the orientation of FIG. 1A).

In the example shown, the mask 101 forms a discontinuous layer extending laterally over and in contact with the face 103T of the substrate 103. In this example, the mask 101 includes disjointed portions laterally delimiting apertures. Mask 101 is, for example, a screen-printing mask. By way of example, mask 101 is made of an insulating material, such as a resin.

The substrate 103 is, for example, a wafer or piece of wafer made of a semiconductor material, such as silicon or germanium nitride (GaN). Although not detailed in FIG. 1A, the substrate 103 includes, for example, at least one unitary electronic component, for example at least one unitary power electronic component. Each unitary electronic component includes, for example, at least one element chosen from among a diode, a thyristor, a triac, a transistor, a resistive, capacitive or inductive load, etc.

In the example shown, contact-making elements 105 are located on and in contact with portions of the face 103T of the substrate 103 not coated with the mask 101. The contact-making elements 105 are connected, for example, to conduction and/or control electrodes of the unitary electronic component(s) formed in the substrate 103. By way of example, the contact-making elements 105 are conductive pads, for example pads made of a metal, such as copper, or a metal alloy. The mask 101 is aligned, for example, with the position of the contact-making elements 105 on the face 103T of the substrate 103. In the example shown in FIG. 1A, two contact-making elements 105 are located in each opening of the mask 101. However, this example is not limitative, as the number of contact elements 105 located in each opening of the mask 101 is, alternatively, different from two.

FIG. 1B illustrates in particular a structure obtained from the structure of FIG. 1A, following a step in which conductive regions 107 are formed in the openings of the mask 101.

In the example shown, the conductive regions 107 fill the openings in the mask 101, i.e., completely fill all the free spaces extending laterally between the parts of the mask 101. In this example, the conductive regions 107 are bordered by the mask 101, the flanks of each conductive region 107 being covered by parts of the mask 101. In the example shown, the conductive regions 107 coat the contact making elements 105 and parts of the face 103T of the substrate 103 not coated by the mask 101 or the contact making elements 105. In the example shown, each conductive region 107 coats two contact making elements 105. In the example shown, the conductive regions 107 are flush with the face of the mask 101 opposite the substrate 103 (the upper face of the mask 101, in the orientation of FIG. 1B).

The conductive regions 107 are made, for example, of a soldering material, such as a soldering paste. At this stage of the process, the material of the conductive regions 107 includes, for example, a metal alloy, for example in the form of metal alloy balls or microballs dispersed in a viscous or pasty material.

In one embodiment, the metal alloy contained in the conductive regions 107 predominantly includes bismuth (Bi). More precisely, the alloy for example has a bismuth content of over 80%, for example of approximately 90%. For example, the alloy also includes at least one additive element selected from silver (Ag), nickel (Ni) and tin (Sn). In this case, for example, the alloy has a content of each additive element of less than 10%, e.g., approximately equal to 5%. By way of example, the metal alloy of the conductive regions 107 has a bismuth content equal to approximately 90%, a silver content equal to approximately 5% and a nickel content equal to approximately 5%. For example, the alloy has a melting point of between 270 and 290° C.

FIG. 1C illustrates in particular a structure obtained from the structure of FIG. 1B, following a step in which the mask 101 is removed, the conductive regions 107 are reflowed and trenches 109 are formed in the conductive regions 107 and the substrate 103.

In the example shown in FIG. 1C, the 101 mask is completely removed.

In the example shown, the conductive regions 107 have been subjected to a reflow phenomenon, for example by carrying out a heating operation to expose the structure to a temperature above the melting point of the metal alloy contained in the conductive regions 107. If the alloy is in the form of balls or microballs dispersed in a flux, this operation melts the balls or microballs and removes the flux. At the end of this operation, each conductive region 107 is substantially made up of the metal alloy. In the example shown, the conductive regions 107 have curved or rounded flanks after reflow. By way of example, the flanks of the conductive regions 107 have a curvature that depends on the surface tension of the metal alloy in the liquid state.

In the example shown, the trenches 109 are substantially aligned with the center of the regions 107. In the orientation shown in FIG. 1C, each trench 109 extends vertically from the top face of one of the conductive regions 107 through the region 107 and penetrates into the thickness of the substrate 103. In the example shown, the trenches 109 do not open on the side of a face 103B of the substrate 103 (the lower face of the substrate 103, in the orientation of FIG. 1C) opposite the face 103T. Each trench 109, for example, is laterally interposed between two contact making elements 105 initially coated with the same region 107. By way of example, the trenches 109 are formed by cutting, for example by sawing, on the face 103T side of the substrate 103.

In the example shown, the unitary electronic component(s) formed in the substrate 103 and intended to form part of a single electronic component 100 are delimited laterally by the trenches 109. When viewed from above, the trenches 109 are for example in the form of a grid, with each cell corresponding to a future electronic component 100. In the example shown, each contact-making element 105 is coated with a portion of one of the conductive regions 107 that is separate from the portions of the conductive regions 107 coating the other contact-making elements 105. In the example shown in FIG. 1C, each future electronic component 100 includes two contact-making elements 105 coated respectively with two separate conductive region portions 107.

FIG. 1D illustrates in particular a structure obtained from the structure shown in FIG. 1C, following a step in which an insulating layer 111 is deposited on the 103T side of the substrate 103, and in which the structure is thinned on the 103T and 103B sides of the substrate 103.

In the example shown, the insulating layer 111 fills, i.e., completely fills, the trenches 109 and all the free spaces extending laterally between the regions 107. By way of example, the insulating layer 111 is made of a resin, for example a molding resin designed to form a packaging around each future electronic component 100.

In the example shown, the structure is thinned, for example by grinding, on the 103T side of the substrate 103 so as to reduce the thickness of the regions 107 and the insulating layer 111. In the example shown, the insulating layer 111 is flush with the face of the regions 107 opposite the substrate 103 (the top face of the regions 107, in the orientation of FIG. 1D).

In addition, the structure is thinned, for example by grinding, on the face 103B side of the substrate 103, so as to expose parts of the insulating layer 111 filling the bottom of the trenches 109. The parts of the insulating layer 111 located inside the trenches 109 are thus flush with the face 103B of the substrate 103. By way of example, the structure is temporarily transferred to a support substrate, or handle, on the 103T side of substrate 103 prior to thinning of the structure on the 103B side, the support substrate then being removed after thinning.

FIG. 1E illustrates in particular a structure obtained from the structure shown in FIG. 1D, following a step in which a further insulating layer 113 is deposited on the 103B side of the substrate 103, and in which the substrate 103 is cut through its entire thickness to separate, or individualize, the electronic components 100.

In the example shown, the insulating layer 113 is located on and in contact with the face 103B of the substrate 103 and with the parts of the insulating layer 111 flush with the face 103B of the substrate 103. The layer 113 is for example made of a resin, for example a molding resin intended to form part of the packaging of electronic components 100. By way of example, the insulating layers 111 and 113 are made of the same material.

In the example shown, the structure includes trenches 115 extending vertically through the thickness of the conductive regions 107 from the face of the conductive regions 107 opposite the substrate 103 (the top face of the conductive regions 107, in the orientation of FIG. 1E). In this example, the trenches 115 have a height, or depth, less than the height, or thickness, of the conductive regions 107. When viewed from above, trenches 115 and 117 surround each electronic component 100.

In the example shown, the structure further includes trenches 117 having a width less than that of the trenches 115. In the example shown, each trench 117 extends vertically from the bottom of one of the trenches 115 through the conductive region 107, the substrate 103 and the insulating layer 113. The trenches 117 thus have an end opening on the 103B side of the substrate 103. In the example shown, the width of the trenches 117 is strictly less than that of the parts of the insulating layer 111 located inside the trenches 109.

For example, the trenches 115 are formed before the trenches 117. For example, the trenches 115 and 117 are formed by sawing.

In the example shown, the trenches 117 delimit parts of the substrate 103, each of which, for example, forms part of an integrated circuit chip 119, or electronic chip, of one of the electronic components 100.

FIG. 2 is a partial schematic cross-sectional view of an electronic device 200 including an electronic component 100 according to one embodiment.

In the example shown, the electronic device 200 includes a support and interconnection substrate 203, for example a printed circuit board. In the illustrated example, contact-making elements 205 are located on and in contact with one face of the support and interconnection substrate 203 (the top face of the support and interconnection substrate 203, in the orientation of FIG. 2). The contact-making elements 205 are connected, for example, to conductive tracks formed on the substrate 203 and/or to conductive vias formed in the thickness of the substrate 203. By way of example, the contacting elements 205 are conductive pads, for example pads made of a metal, such as copper, or a metal alloy.

In the illustrated example, the electronic component 100 is attached to the support and interconnection substrate 203 by conductive regions 207 interposed between the component 100 and the substrate 203. More specifically, in this example, each conductive region 207 is interposed between one of the conductive regions 107 of the electronic component 100 and one of the contact-making elements 205 of the support and interconnection substrate 203. Each contact-making element 205 of the support and interconnection substrate 203 is thus connected to one of the contact-making elements 105 of the electronic component 100 via one of the conductive regions 207 and one of the conductive regions 107.

The conductive regions 207 are made of a metal alloy, for example a metal alloy with a melting point strictly lower than that of the metal alloy of the conductive regions 107. By way of example, the conductive regions 207 are made of a lead-free alloy, for example an alloy of tin, silver and copper (Sn—Ag—Cu alloy) also known by the acronym SAC.

In the example shown, the conductive regions 207 coat a face of the conductive regions 107 located on the side of the support and interconnection substrate 203 (the bottom face of the conductive regions 107, in the orientation of FIG. 2). Furthermore, in this example, the conductive regions 207 coat part of the flank of the conductive regions 107, i.e., wet the flanks of the conductive regions 107.

FIG. 2 illustrates an example in which the electronic device 200 includes a single electronic component 100. However, this example is not limitative, as the electronic device 200 includes any number of electronic components of the type of component 100 in some embodiments. By way of example, the electronic device 200 is integrated into a motor vehicle, with the electronic component 100 implementing, for example, a protection function against electrostatic discharges to which the electronic device 200 may be exposed.

An advantage of the electronic component 100 is that the presence of conductive regions 107 with a high bismuth content makes it possible to obtain wettable flanks. This makes it easier to inspect the soldering of component 100 to support and interconnect substrate 203. Another advantage of using conductive regions 107 made of a metal alloy with a high bismuth content is that it avoids problems of unintentional overbridging, or interconnection, between adjacent integrated circuit chips during the step of reflow of the material of the conductive regions 107 prior to the cutting step aimed at individualizing the integrated circuit chips. This is due in particular to the fact that the metal alloy with a high bismuth content has a higher surface tension in the liquid state than known alloys, in particular the SAC alloy.

In addition, the high-bismuth alloy has the advantage that it can be used to replace expensive alloys, such as gold-tin alloy, for the production of solder joints in a material with a melting point strictly higher than that of the SAC alloy. In this case, the high-bismuth alloy, for example, at least partially coats a bottom face of an integrated circuit chip superimposed on another integrated circuit chip, for example of the type of the chip 119 previously described in relation with FIG. 1E.

Various embodiments and variants have been described. The person skilled in the art will understand that certain features of these embodiments and variants could be combined, and other variants will readily occur to those skilled in the art.

Finally, the practical implementation of the embodiments and variants described herein is within the capabilities of those skilled in the art based on the functional description provided hereinabove. In particular, the bismuth content in the metal alloy of the conductive regions 107 can be adjusted according to the application, for example in order to obtain a compromise between an increase in the surface tension of the alloy in the liquid state, obtained by increasing the bismuth content in the alloy, and an increase in the wettability of the flanks of the electronic components 100, obtained by decreasing the bismuth content in the alloy.

An electronic component (100) includes an integrated circuit chip (119); a package (111, 113) surrounding the integrated circuit chip; and at least a first conductive region (107) at least partially coating one side of the integrated circuit chip, the first conductive region including an alloy predominantly including bismuth.

In one embodiment, the alloy has a bismuth content of over 80%, preferably equal to approximately 90%.

In one embodiment, the alloy further includes at least one additive element selected from silver, nickel and tin.

In one embodiment, the alloy has a content of the at least one additive element of less than 10%, preferably equal to approximately 5%.

In one embodiment, the alloy has: a bismuth content equal to approximately 90%; a silver content equal to approximately 5%; and a nickel content equal to approximately 5%.

In one embodiment, the alloy has a melting point of between 27° and 290° C.

An electronic device (200) includes a support and interconnection substrate (203); at least one contact-making element (205) located on one face of the support and interconnection substrate; at least one electronic component (100); and at least one second conductive region (207) interposed between the at least one contact making element and the at least one first conductive region (107) of the electronic component.

In one embodiment, the second conductive region (207) covers a flank of the electronic component (100).

In one embodiment, the second conductive region (207) is made of an alloy of tin, silver and copper.

A motor vehicle includes at least one device (200).

A method of manufacturing an electronic component (100) includes an integrated circuit chip (119) and a package (111, 113) surrounding the integrated circuit chip, the method including the step of at least partially coating a face of the integrated circuit chip with a first conductive region (107) including an alloy predominantly comprising bismuth.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device comprising:
an integrated circuit chip;
a package surrounding the integrated circuit chip; and
at least a first conductive region at least partially coating one side of the integrated circuit chip, the first conductive region including an alloy of at least 50% bismuth.

2. The device according to claim 1, wherein the alloy has a bismuth content of over 80%.

3. The device of claim according to claim 2, wherein the alloy has a bismuth content approximately equal to 90%.

4. The device according to claim 1, wherein the alloy further includes at least one additive element selected from silver, nickel and tin.

5. The device according to claim 4, wherein the alloy has a content of the at least one additive element of less than 10%.

6. The device according to claim 5, wherein the alloy has a content of the at least one additive element equal to approximately 5%.

7. The component according to claim 1, wherein the alloy has:
a bismuth content equal to approximately 90%;
a silver content equal to approximately 5%; and
a nickel content equal to approximately 5%.

8. The device according to claim 1, wherein the alloy has a melting point of between 27° and 290° C.

9. The electronic device of claim 1, comprising:
a support and interconnection substrate;
at least one contact-making element located on one face of the support and interconnection substrate; and
at least one second conductive region interposed between the at least one contact making element and the at least one first conductive region.

10. The device according to claim 9, wherein the second conductive region covers a flank of the first conductive region.

11. The device according to claim 9, wherein the second conductive region is made of an alloy of tin, silver and copper.

12. A method, comprising:
surrounding an integrated circuit chip with a package, including:
at least partially coating a front face of an integrated circuit chip with a first conductive region including an alloy of at least 50% bismuth; and
forming an encapsulation layer on sidewalls and a back face of the integrated circuit chip.

13. The method of claim 12, wherein at least partially coating the front face includes depositing a first portion of the alloy on a first contact making element and depositing a second portion of the alloy on a second contact making element on the front face, the first and second portions being separated by a gap.

14. The method of claim 13, comprising filling the gap with the encapsulation layer.

15. The method of claim 14, comprising:
forming a second conductive region on a substrate; and
positioning the package on the second conductive region, the second conductive region being positioned on a sidewall of the first conductive region.

16. The method of claim 15, wherein the second conductive region is made of an alloy of tin, silver and copper.

17. The method of claim 14, comprising performing a reflow process of the first conductive region prior to filling the gap with the encapsulation layer.

18. A motor vehicle, comprising:
an electronic device including:
a substrate; and
a package on the substrate, the package including:
an integrated circuit chip;
an encapsulation layer on a first face and on sidewalls of the integrated circuit chip; and
a first conductive region at least partially coating a second face of the integrated circuit chip, the first conductive region including an alloy of at least 50% bismuth.

19. The motor vehicle of claim 18, wherein the electronic device includes a second conductive region on the substrate between the substrate and the package, the second conductive region positioned on a sidewall of the first conductive region.

20. The motor vehicle of claim 19, wherein the second conductive region is made of an alloy of tin, silver and copper.
